(19) United States
(12) Patent Application Publication
(10) Pub. No.: US 2002/0108085 A1
(43) Pub. Date: Aug. 8, 2002

(54) System and method for performing joint trellis coded modulation (TCM) with multi-circular constellations on data being transmitted over nonlinear channels

(76) Inventors: Mustafa Eroz, Germantown, MD (US); Enrique Laborde, Gaithersburg, MD (US)

Correspondence Address: Hughes Electronics Corporation, Patent Docket Administration, Bldg. 1, Mail Stop A109, P.O. Box 956, El Segundo, CA, 90245-0956, US

(21) Appl. No.: 10/053,395

(22) Filed: Oct. 23, 2001

Related U.S. Application Data
(60) Provisional application No. 60/266,050, filed on Feb. 2, 2001.

(51) Int. Cl. H03M 13/00

(52) U.S. Cl. 714/758; 714/790

(57) ABSTRACT

A system and method for performing joint trellis coded modulation (TCM) with multi-circular constellations on data being transmitted over nonlinear channels without incurring substantial losses in transmission power. The system and method each employs a first constituent encoder, such as a convolutional encoder, adapted to encode the data to output first encoded data, an interleaver, adapted to interleave the data to produce interleaved data, and a second constituent encoder, such as a convolutional encoder, adapted to encode the interleaved data to output second encoded data. The system and method each further employs a modulator, adapted to modulate the first and second encoded data in accordance with modulation symbols mapped in a multi-circular constellation, to reduce power loss during transmission of the modulated first and second encoded data over a non-linear channel. The multi-circular constellation can includes two concentric circles, each having different radii, with a number of the symbols in one of the circles being different from a number of the symbols in the other circle. The system and method each further employs a deinterleaver, adapted to deinterleave the second encoded data after the second encoded data has been modulated by the modulator, and a puncturer, adapted to puncture the first and second modulated encoded data.

The present application claims benefit under 35 U.S.C. §119(e) of a U.S. Patent Application Serial No. 60/266,050, filed Feb. 2, 2001, the entire contents of which is incorporated herein by reference.

### BACKGROUND OF THE INVENTION

1. Field of the Invention

The present invention relates to a system and method for performing joint trellis coded modulation (TCM) with multi-circular constellations on data being transmitted over non-linear channels. More particularly, the present invention relates to an improved turbo encoding system and method for efficiently and effectively transmitting data over nonlinear channels without incurring substantial losses in transmission power.

2. Description of the Related Art

As bandwidth and power are two scarce resources of almost any communication system, it is desirable to design both bandwidth and power efficient links. While trellis coded modulation (TCM) is particularly useful for bandwidth efficient communication, turbo codes are known to achieve reliable communication at very low signal to noise ratios (SNR). To achieve bandwidth and power efficient systems, it is therefore natural to combine TCM and turbo codes.

An example of a turbo encoder system 100 for performing turbo-coded TCM using 16-QAM modulation will now be described with reference to FIGS. 1-3. As shown in FIG. 1, turbo encoder system 100 includes two constituent encoders 102 and 104 separated by an interleaver 106 as can be appreciated by one skilled in the art. In this example, each constituent encoder 102 and 104 is recursive, systematic, rate ¾ convolutional encoder. A block of N groups of three information bits (i.e., 3N bits) are encoded block by block by the turbo encoder system 100. The symbolwise turbo interleaver 106 changes the order of information bits before encoding by the second constituent encoder 104 is performed. The interleaving is done without breaking the order within the groups of three bits, and is thus commonly referred to as symbolwise interleaving.

At the output of each constituent encoder, each group of four coded bits is mapped to a respective 16-QAM symbol 108 and 110. The output 16-QAM symbols of the second constituent encoder 104 are then deinterleaved by a symbolwise deinterleaver 112. Finally the 16-QAM symbols are alternately transmitted and punctured from the first and second constituent encoders 102 and 104. That is, the symbols are transmitted in the following order: the first symbol of the first encoder 102, followed by the second deinterleaved symbol of the second encoder 104, followed by the third symbol of the first encoder 102, followed by the fourth deinterleaved symbol of the second encoder 104, and so on. Such an alternate transmit/puncture scheme provides a throughput of 3 information bits/transmitted symbol, ignoring tail bits. Additional puncturing will be needed to increase the throughput.

The constituent encoders 102 and 104 are terminated as follows. After all the information bits are encoded, tail bits for the first constituent encoder are chosen as,

u₀=s₂ u₁=s₀ u₂=s₁

Similarly, tail bits for the second constituent encoder are chosen as,

u′₀=s′₂ u′₁=s′₀ u′₂=s′₁

The total of 6 tail bits will bring both of the constituent encoders 102 and 104 back to all zero state by transmitting a total of two 16-QAM symbols (one symbol for the first constituent encoder 102 and the other symbol for the second constituent encoder 104). It is noted that these terminating 16-QAM symbols are never punctured. Rather, they are transmitted after all of the information bit carrying 16-QAM symbols are transmitted.

The signal constellation mapping for 16-QAM is shown in FIG. 2, and the performance of the turbo encoder 100 performing the above-described turbo coded TCM using 16-QAM over linear and nonlinear channels of different back-offs is shown in FIG. 3. As can be appreciated from FIG. 3, an output back-off of around 1.75 dB seems to be the best trade-off in terms of total power consumption for this system 100. On the other hand, at that back-off, the performance of the system degrades by about 2.0 dB due to the distortion caused by the nonlinear channel.

Further descriptions of turbo encoders are set forth in the following publications, all of which are incorporated in their entirety herein by reference: S. Le Goff, A. Glavieux and C. Berrou, entitled “Turbo-codes and high spectral efficiency modulation”, Proc. ICC '94, May 1994, pp. 645-649; P. Robertson and T. Woerz, “A novel bandwidth efficient coding scheme employing turbo codes”, Proc. ICC '96, June 1996, pp. 962-967; S. Benedetto, D. Divsalar, G. Montorsi and F. Pollara, “Parallel concatenated trellis coded modulation”, Proc. ICC'96, June 1996, pp. 974-978; G. Underboeck, “Channel coding with multilevel phase signals”, IEEE Trans. On Inform. Theory, Vol. IT-28, pp.55-67, January 1982; P. Robertson and T Worz, “Bandwidth-Efficient Turbo Trellis-Coded Modulation using punctured components codes”, IEEE Journal on Selected Areas in Comm, Vol. 16, pp206-218, February 1998; and X. Dong, N. C. Beaulieu, P. H. Wittke, “Signaling Constellations for Fading Channels”, IEEE Trans. Commun., Vol. 47, pp 703-713, May 1999. Even though the turbo coded TCM systems described in these publications may operate somewhat effectively for transmitting data over linear channels, these systems suffer large power losses when transmitting data over nonlinear channels.

Accordingly, a need exists for an improved turbo encoding system that is capable of efficiently and effectively transmitting data over nonlinear channels without incurring substantial losses in transmission power.

### SUMMARY OF THE INVENTION

An object of the present invention is to provide an improved turbo encoding system and method for efficiently and effectively transmitting data over nonlinear channels without incurring substantial losses in transmission power.

Another object of the present invention is to provide a system and method for performing joint trellis coded modulation (TCM) with multi-circular constellations on data being transmitted over non-linear channels.

These and other objects are substantially achieved by providing a system and method for turbo encoding data, employing a first constituent encoder, such as a convolutional encoder, adapted to encode the data to output first encoded data, an interleaver, adapted to interleave the data to produce interleaved data, and a second constituent encoder, such as a convolutional encoder, adapted to encode the interleaved data to output second encoded data. To reduce power loss during the transmission of modulated data, the system and method each employs a modulator for mapping over symbols in a circular constalleation the first and second data. The multi-circular constellation can includes two or more circles, each having different radii, with a number of the symbols in one of the circles being different from a number of the symbols in the other circle. For example, one of the circles is concentric with the other circle in the multi-circular constellation, and a number of the symbols in the outer circle is greater than a number of the symbols in the inner circle. The multi-circular constellation can include any appropriate number of symbols, for example, 16 symbols. The system and method each further employs a deinterleaver, adapted to deinterleave the second encoded data after the second encoded data has been modulated by the modulator, and a puncturer, adapted to puncture the first and second modulated encoded data.

### BRIEF DESCRIPTION OF THE DRAWINGS

These and other objects and advantages of the invention will become more apparent and more readily appreciated from the following detailed description of the presently preferred exemplary embodiments of the invention taken in conjunction with the accompanying drawings, of which:

FIG. 1 is a block diagram of a turbo encoder system for performing turbo-coded TCM using 16-QAM modulation;

FIG. 2 is a diagram of a signal mapping for 16-QAM modulation employed in the system shown in FIG. 1;

FIG. 3 is a graph showing an example of bit error rate versus power loss experienced by the system shown in FIG. 1;

FIG. 4 is a block diagram of a turbo encoder system according to an embodiment of the present invention;

FIG. 5 is a diagram of a signal mapping for 16-symbol modulation employed in the system shown in FIG. 4;

FIG. 6 is another diagram of a signal mapping for 16-symbol modulation employed in the system shown in FIG. 4;

FIG. 7 is a further diagram of a signal mapping for 16-symbol modulation employed in the system shown in FIG. 4; and

FIG. 8 is a graph showing an example of bit error rate versus power loss experienced by the system shown in FIG. 4 in relation to the bit error rate versus power loss experienced by the system shown in FIG. 1.

### DETAILED DESCRIPTION OF THE PREFERRED EMBODIMENTS

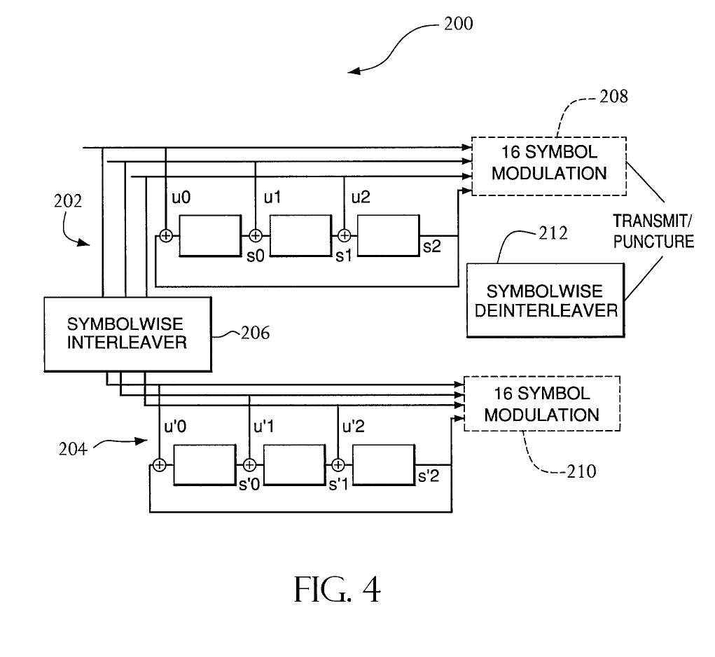

An embodiment of the present invention will now be described with reference to FIGS. 4-8. Specifically, according to an embodiment of the present invention, the turbo encoder system 200 includes two constituent encoders 202 and 204 separated by an interleaver 106. In this example, each constituent encoder 202 and 204 can be a recursive, systematic, rate ¾ convolutional encoder, or any other suitable type and rate encoder. A block of N groups of three information bits (i.e., 3N bits) are encoded block by block by the turbo encoder system 200. The symbolwise turbo interleaver 206 changes the order of information bits before encoding by the second constituent encoder 204 is performed. The interleaving is done without breaking the order within the groups of three bits, and is thus commonly referred to as symbolwise interleaving.

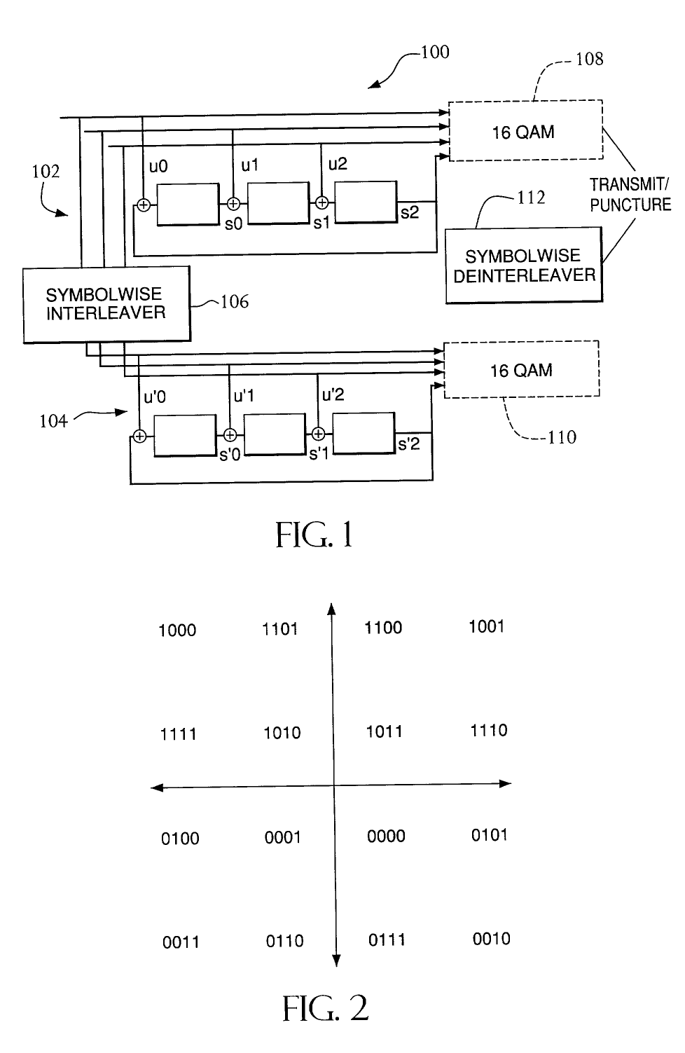

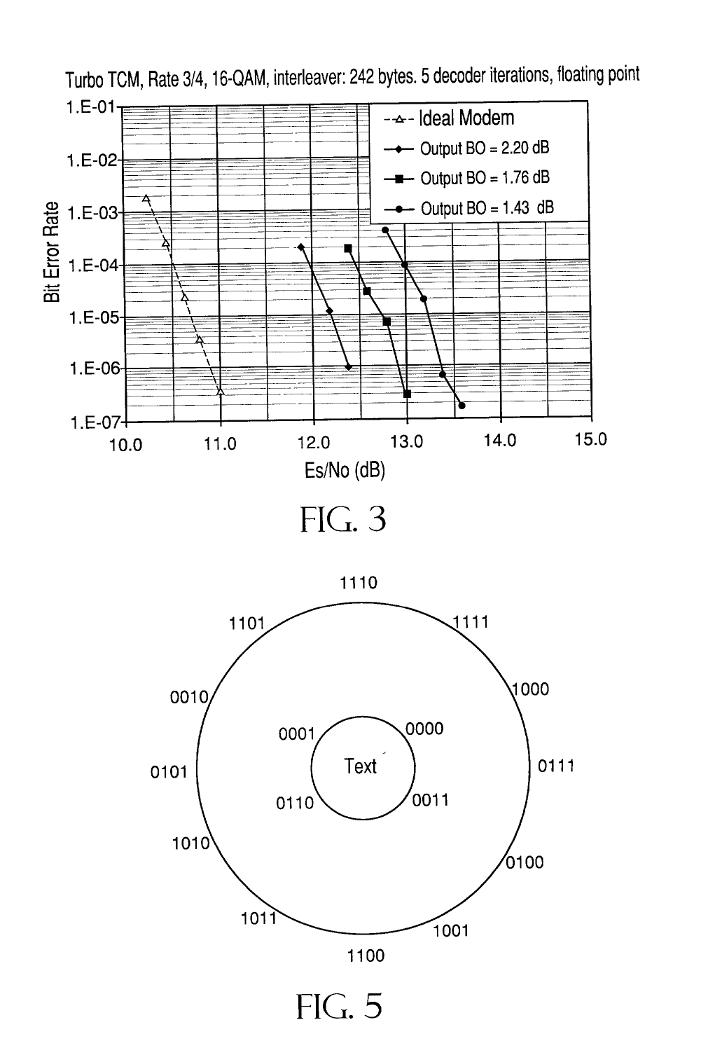

Instead of mapping the output of each constituent encoder 202 and 204 to a respective 16-QAM symbol having the mapped constellation as shown in FIG. 2, each group of four coded bits output of each constituent encoder 202 and 204 is mapped to a respective 16-symbol modulation 208 and 210 having the constellation as mapped in FIG. 5. The 16-symbol modulation as mapped in multi-circular constellations in FIG. 5 is a “nonlinearity-friendly” modulation scheme. Non-linear channels are typically associated with the power amplification of radio frequency signals which cause signal distortion that is also known as amplitude modulation to amplitude modulation (AM/AM) and amplitude modulation to phase modulation (AM/PM) conversions. Turbo TCM with multi-circular constellations achieve better performance over nonlinear channels because of its reduced peak to average amplitude ratio relative to more conventional constellations such as quadrature amplitude modulation. The 16-symbol modulation 208 and 210 thus enable the turbo encoder TCM system 200 to require around 1.0 dB less SNR over nonlinear channels compared to the best turbo coded TCM systems described in the publications cited in the Background section above. The turbo coded TCM system 200 thus improves the performance over nonlinear channels compared to the best conventional turbo coded TCM having the same bandwidth efficiency. Moreover, the use of the 16-symbol modulation as shown in FIG. 4 introduces no additional implementation complexity to the system 200.

The output 16-symbol modulation symbols of the second constituent encoder 204 are then deinterleaved by a symbolwise deinterleaver 212. Finally the 16-symbol modulation symbols are alternately transmitted and punctured from the first and second constituent encoders 202 and 204. That is, the symbols are transmitted in the following order: the first symbol of the first encoder 202, followed by the second deinterleaved symbol of the second encoder 204, followed by the third symbol of the first encoder 202, followed by the fourth deinterleaved symbol of the second encoder 204, and so on. Such an alternate transmit/puncture scheme provides a throughput of 3 information bits/transmitted symbol, ignoring tail bits. Additional puncturing will be needed to increase the throughput.

As with the encoders 102 and 104 in system 100 described in the Background section above, the constituent encoders 202 and 204 can be terminated as follows. After all the information bits are encoded, tail bits for the first constituent encoder 202 are chosen as,

u₀=s₂ u₁=s₀ u₂=s₁

Similarly, tail bits for the second constituent encoder 204 are chosen as,

u′₀=s′₂ u′₁=s′₀ u′₂=s′₁

The total of 6 tail bits will bring both of the constituent encoders 202 and 204 back to all zero state by transmitting a total of two 16-symbol modulation symbols (one symbol for the first constituent encoder 202 and the other symbol for the second constituent encoder 204). It is noted that these terminating 16-symbol modulation symbols are never punctured. Rather, they are transmitted after all of the information bit carrying 16-symbol modulation symbols are transmitted.

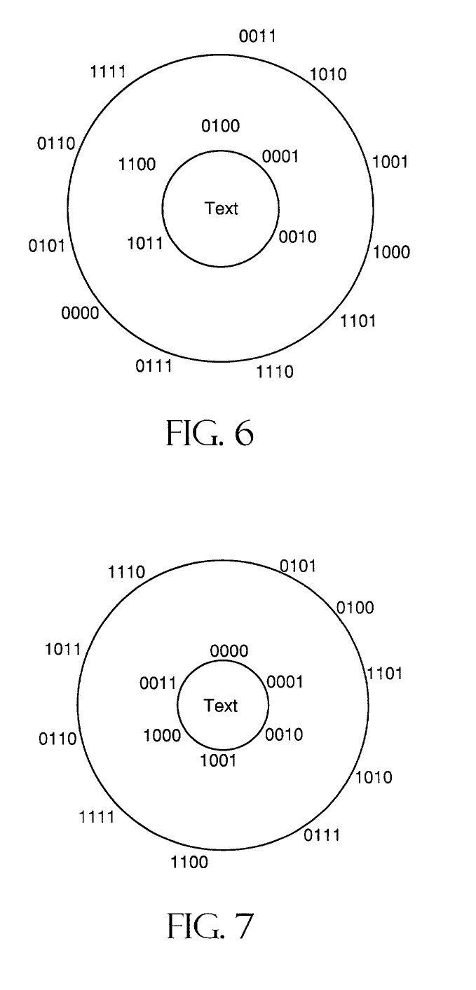

It is noted that the 16-symbol modulation 208 and 210 need not have the constellation as shown in FIG. 5. Rather, the 16-symbol modulation 208 and 210 can have different numbers of symbols on the inner circle, different symbol labeling, and various ratios of the outer circle to inner circle radii, such as those shown in FIGS. 6 and 7, can also be used with various coding gains over nonlinear channels.

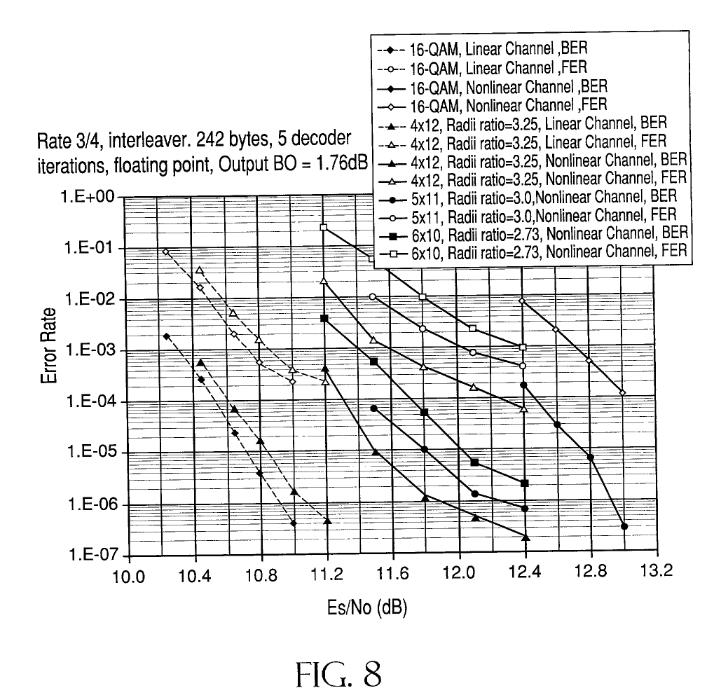

It is further noted that the turbo coded TCM system 200 performs about 1.0 dB better than the systems in the above papers over nonlinear channels at the same throughput and the same implementation complexity. For example, FIG. 8 is a graph showing a simulation of turbo encoder TCM system 200 using 16-symbol modulator 208 and 210 having the constellations shown in FIGS. 5-7 over linear and nonlinear channels. Even though joint turbo-TCM and two circle configurations may be somewhat inferior to turbo-TCM using 16-QAM over linear channels, they outperform 16-QAM systems over nonlinear channels up to 1.0 dB at BER=10⁻⁶.

It should be further noted that the same ideas of the invention can be applied to other turbo-coded TCM approaches, to other code rates and to other modulation schemes with possibly different number of symbols as well.

Although only a few exemplary embodiments of the present invention have been described in detail above, those skilled in the art will readily appreciate that many modifications are possible in the exemplary embodiments without materially departing from the novel teachings and advantages of this invention. Accordingly, all such modifications are intended to be included within the scope of this invention as defined in the following claims.

What is claimed is:

1. A system for turbo encoding data, comprising:
a first constituent encoder, adapted to encode said data to output first encoded data;
an interleaver, adapted to interleave said data to produce interleaved data;
a second constituent encoder, adapted to encode said interleaved data to output second encoded data; and
a modulator, adapted to modulate said first and second encoded data in accordance with modulation symbols mapped in a multi-circular constellation, to reduce power loss during transmission of said modulated first and second encoded data over a non-linear channel.

2. A system as claimed in claim 1, wherein:
said multi-circular constellation includes at least two circles, each having different radii.

3. A system as claimed in claim 2, wherein:
said multi-circular constellation includes two of said circles.

4. A system as claimed in claim 2, wherein:
said multi-circular constellation includes more than two of said circles.

5. A system as claimed in claim 2, wherein:
a number of said symbols in one of said circles is different from a number of said symbols in any of the other said circles.

6. A system as claimed in claim 2, wherein:
all of said circles are concentric to form said multi-circular constellation.

7. A system as claimed in claim 2, wherein:
a number of said symbols in the outer said circles increase relative to those in the inner said circles.

8. A system as claimed in claim 1, wherein:
said multi-circular constellation includes at least 16 symbols.

9. A system as claimed in claim 8, wherein:
said multi-circular constellation includes 16 said symbols.

10. A system as claimed in claim 8, wherein:
said multi-circular constellation includes more than 16 said symbols.

11. A system as claimed in claim 1, further comprising:
a deinterleaver, adapted to deinterleave said second encoded data after said second encoded data has been modulated by said modulator.

12. A system as claimed in claim 1, further comprising:
a puncturer, adapted to puncture said first and second modulated encoded data.

13. A system as claimed in claim 1, wherein:
each of said first and second encoders includes a convolutional encoder.

14. A method for turbo encoding data, comprising:
encoding said data to output first encoded data;
interleaving said data to produce interleaved data;
encoding said interleaved data to output second encoded data; and
modulating said first and second encoded data in accordance with modulation symbols mapped in a multi-circular constellation, to reduce power loss during transmission of said modulated first and second encoded data over a non-linear channel.

15. A method as claimed in claim 14, wherein:
said multi-circular constellation includes at least two circles, each having different radii.

16. A method as claimed in claim 15, wherein:
said multi-circular constellation includes two of said circles.

17. A method as claimed in claim 15, wherein:
said multi-circular constellation includes more than two of said circles.

18. A method as claimed in claim 15, wherein:
a number of said symbols in one of said circles is different from a number of said symbols in any of the other said circles.

19. A method as claimed in claim 15, wherein:
all of said circles are concentric to form said multi-circular constellation.

20. A method as claimed in claim 15, wherein:
a number of said symbols in the outer said circles increase relative to those in the inner said circles.

21. A method as claimed in claim 14, wherein:
said multi-circular constellation includes at least 16 symbols.

22. A method as claimed in claim 21, wherein:
said multi-circular constellation includes 16 said symbols.

23. A method as claimed in claim 21, wherein:
said multi-circular constellation includes more than 16 said symbols.

24. A method as claimed in claim 14, further comprising:
deinterleaving said second encoded data after said second encoded data has been modulated.

25. A method as claimed in claim 14, further comprising:
puncturing said first and second modulated encoded data.

26. A method as claimed in claim 14, wherein:
each of said encoding includes convolutional encoding.
